(19) United States
(12) Patent Application Publication
(10) Pub. No.: US 2012/0025190 A1
(43) Pub. Date: Feb. 2, 2012

(54) Radiation detector

(75) Inventor: Yoshihiro Okada, Kanagawa (JP)

(73) Assignee: FUJIFILM Corporation, Tokyo (JP)

(21) Appl. No.: 13/067,224

(22) Filed: May 18, 2011

(30) Foreign Application Priority Data
May 21, 2010 (JP) 2010-117822

(51) Int. Cl. H01L 31/0392; H01L 31/0232

(52) U.S. Cl. 257/57; 257/71; 257/E31.041; 257/E31.129

(57) ABSTRACT

The present invention provides a radiation detector that may set output characteristics of an electrical signal for output so as to match the detection range of an amplifier. Namely, a charge storage capacitor is provided to each sensor section so as to be electrically connected to a bias line in parallel to the respective sensor section.

### CROSS-REFERENCE TO RELATED APPLICATION

This application claims priority under 35 USC 119 from Japanese Patent Application No. 2010-117822 filed on May 21, 2010, the disclosure of which is incorporated by reference herein.

### BACKGROUND OF THE INVENTION

1. Field of the Invention

The present invention relates to a radiation detector. The present invention particularly relates to a radiation detector with plural pixels arrayed in a matrix, in which charges generated by irradiation with radiation are accumulated, and the amount of accumulated charges are detected as image information.

2. Description of the Related Art

Radiographic imaging apparatuses are recently being implemented that employ radiation detectors having a X-ray sensitive layer disposed on a TFT (thin film transistor) active matrix substrate, and directly converting X-ray information into digital information, such as, for example, a FPD (flat panel detector) radiation detector. Such radiation detectors have the advantage that, in comparison to related imaging plates, images can be more immediately checked and video images can also be checked. The introduction of such radiation detectors is proceeding rapidly.

Various types are proposed for such radiation detectors. There are, for example, direct-conversion-type radiation detectors that convert radiation directly to charge in a semiconductor layer, and accumulate the charge. There are also indirect-conversion-type radiation detectors that first convert radiation into light with a scintillator, such as CsI:Tl, GOS (Gd₂O₂S:Tb) or the like, then convert the converted light into charge and accumulate the charge. Radiation detectors output an electrical signal according to the charge accumulated in each photo diode. In a radiographic imaging apparatus, the electrical signal output from the radiation detector is converted into digital information in an analogue/digital (A/D) converter after the signal has been amplified by an amplifier.

However, amplifier is capable for amplifying a defined range of electrical signals.

Consequently there are sometimes cases when, out of the signal levels of electrical signals output from the radiation detector, the range of signal levels employed for a radiographic image (called the dynamic range) does not fall within the detection range of the amplifier. A mismatch can arise between the dynamic range of the electrical signal output from the photo diode and the detection range of the amplifier, particularly when a general purpose amplifier is employed and there is commonality between multiple products.

When such a mismatch arises, this can be addressed by employing an amplifier with a wider detection range. However, the dynamic range of the electrical signal may become smaller than the amplifier detection range, and may results in lowering the S/N ratio.

As related technology, a technique is proposed in Japanese Patent Application Laid-Open (JP-A) No. 2008-270765 for obtaining an output voltage over a wide range of illumination intensities. In this technique, the output terminal of a photo diode and the drain terminal of a MOS transistor are connected together, and the drain terminal and the gate terminal of the MOS transistor are also connected together. In this technique, the voltage generated is detected at the gate terminal of the MOS transistor according to the current generated in the photo diode.

There is also a technique proposed in JP-A No. 2002-350551 for enabling the amount of charges accumulate in an accumulation capacitor to be varied. In this technique, a MIS accumulation capacitor is provided on the ground side of a photo diode, and the MIS accumulation capacitor is connected to a switch such that connection can be made to the positive potential side of a power source or to a GND potential. In this technique, the potential of the accumulation capacitor is switched over by the switch, such that the accumulation capacitor operates in either an accumulation state or a depletion state.

However, the techniques of JP-A No. 2008-270765 and JP-A No. 2002-350551, cannot eliminate the mismatch between the dynamic range of the electrical signal output from the radiation detector and the detection range of the amplifier.

### SUMMARY OF THE INVENTION

The present invention provides a radiation detector that may set output characteristics of an output electrical signal to match a detection range of an amplifier.

A first aspect of the present invention is a radiation detector including: a plurality of scan lines provided parallel to each other; a plurality of signal lines provided parallel to each other and intersecting with the scan lines; a plurality of sensor sections, provided at intersecting portions of the scan lines and the signal lines, that generate charges due to irradiation of radiation, and that accumulate charges according to an amount of irradiated radiation; a plurality of bias lines that apply a bias voltage to the plurality of sensor sections; arid a plurality of charge storage capacitors, provided for each of the plurality of sensor sections, that accumulate charges generated in the sensor sections and are electrically connected to the bias lines in parallel to the sensor sections.

In the first aspect of the present invention, plural charge storage capacitors that accumulate charges generated in the sensor sections are provided, and the charge storage capacitor is provided for each of the plural sensor sections. Accordingly, in the first aspect of the present invention, the gain characteristics of electrical signal output from the radiation detector can be set to desired slope, according to the capacity of the charge storage capacitors. Accordingly, in the first aspect of the present invention, the output characteristics of the electrical signal output can be set to match the detection range of the amplifier.

A second aspect of the present invention, in the above aspect, may further include a light emitting section, provided above a detection region where the plurality of sensor sections are provided, that generates light according to irradiated radiation, wherein the plurality of bias lines may be provided at a downstream side from the sensor portions in a direction of the light generated in the light emitting sections, such that the bias lines overlap with the sensor sections with an insulation film disposed between the sensor sections and the bias lines, the bias lines may be connected to the sensor sections through contacts formed through the insulation film.

A third aspect of the present invention, in the above aspects, may further include a thin film transistor that reads charge generated in the plurality of sensor sections, wherein the plurality of charge storage capacitors may be configured with two electrodes and an insulation film disposed between the two electrodes, and one of the electrodes may be formed in a wiring layer in which the thin film transistor is formed.

A fourth aspect of the present invention, in the above aspects, the insulation film of the plurality of charge storage capacitors may be formed by an insulation layer that configures a gate insulation film of the thin film transistor.

According to the above aspects, the present invention can set the output characteristics of an electrical signal output to match the detection range of an amplifier.

### BRIEF DESCRIPTION OF THE DRAWINGS

An exemplary embodiment of the present invention will be described in detail based on the following figures, wherein:

FIG. 1 is a configuration diagram of a radiographic imaging apparatus according to an exemplary embodiment;

FIG. 2 is plan view illustrating a configuration of a radiation detector according to an exemplary embodiment;

FIG. 3 is a cross-section of a radiation detector according to an exemplary embodiment, taken on line A-A of FIG. 2;

FIG. 4 is a cross-section of a radiation detector according to an exemplary embodiment, taken on line B-B of FIG. 2;

FIG. 5 is a cross-section of a radiation detector according to an exemplary embodiment, taken on line C-C of FIG. 2;

FIG. 6 is a configuration diagram of a radiation detector of a radiographic imaging apparatus according to an exemplary embodiment;

FIG. 7 is an equivalent circuit diagram focusing on a single pixel of a radiation detector according to an exemplary embodiment; and

FIG. 8 is a graph illustrating sensitivity characteristics of a radiation detector according to an exemplary embodiment.

### DETAILED DESCRIPTION OF THE INVENTION

Explanation follows regarding an exemplary embodiment for implementing the present invention, with reference to the drawings.

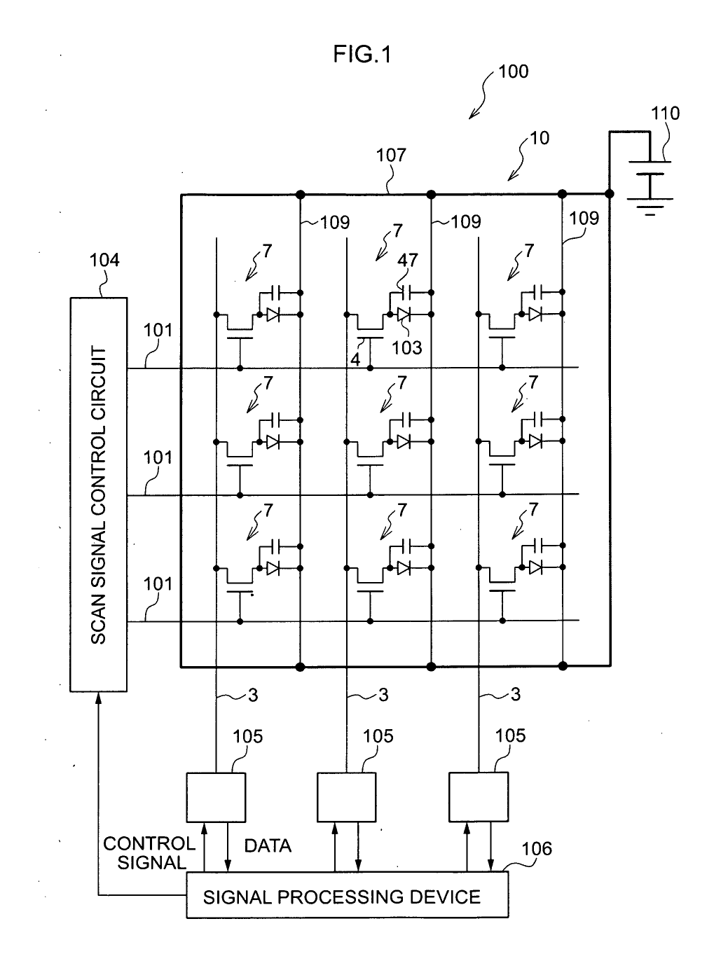

FIG. 1 is a diagram illustrating the overall configuration of a radiographic imaging apparatus 100 according to the present exemplary embodiment.

As shown in FIG. 1, the radiographic imaging apparatus 100 according to the present exemplary embodiment is equipped with an indirect conversion radiation detector 10.

The radiation detector 10 is provided with plural pixels 7 disposed along one direction (the across direction in FIG. 1, referred to below as the “row direction”) and a direction that intersects with the row direction (the vertical direction in FIG. 1, referred to below as the “column direction) so as to form a 2-dimensional shape. Each of the pixels 7 is configured to include a sensor section 103, a charge storage capacitor 47 and a TFT switch 4. The sensor section 103 receives light emitted by a scintillator, described below, and accumulates charges. The charge storage capacitor 47 is electrically connected in parallel to the sensor section 103. TFT switch 4 reads out the charge that has accumulated in the sensor section 103 and the charge storage capacitor 47.

The radiation detection device 10 is provided with plural scan lines 101 that run parallel to each other along the row direction, and that switch the TFT switches 4 ON/OFF. The radiation detection device 10 is also provided with plural signal lines 3 that run parallel to each other along the row direction, and that read out the charges accumulated in the sensor sections 103. There are also common electrode lines 109 provided in the radiation detector 10 running parallel to the signal lines 3.

A line 107 is additionally provided in the radiation detector 10 so as to surround the 2-dimensional shaped detection region where the pixels 7 are provided. The line 107 is connected to a power supply 110 supplying a specific bias voltage. Both ends of each of the common electrode lines 109 are connected at to the line 107. One end of the sensor section 103 and one end of the charge storage capacitor 47 of each of the pixels 7 are connected to the respective common electrode line 109, and bias voltage is applied to each of the sensor sections 103 and each of the charge storage capacitors 47 through the line 107 and the common electrode line 109.

An electrical signal, corresponding to the amount of accumulated charges in the sensor section 103 and the charge storage capacitor 47, flows in each of the signal lines 3 by switching ON the TFT switch 4 in one or other of the pixels 7 connected to this signal line 3. A signal detection circuit 105 is connected to each of the signal lines 3 for detecting the electrical signal flowing out from each of the signal lines 3. A scan signal control circuit 104 is also connected to the scan lines 101 for outputting a control signal to each of the scan lines 101 for ON/OFF switching of the TFT switches 4.

The signal detection circuits 105 are each inbuilt with an amplifier circuit for each of the respective signal lines 3, and the amplifier circuits amplify input electrical signals. Electrical signals input by each of the signal lines 3 are amplified by the amplifier circuits in the signal detection circuit 105. The signal detection circuits 105 thereby detect the charge amount that has been accumulated in each of the sensor sections 103 as information for each pixel configuring an image.

A signal processing device 106 is connected to the signal detection circuits 105 and the scan signal control circuit 104. The signal processing device 106 executes specific processing on the electrical signals detected by the signal detection circuits 105. The signal processing device 106 also outputs a control signal expressing the timing of signal detection to the signal detection circuits 105, and outputs a control signal expressing the timing of scan signal output to the scan signal control circuit 104.

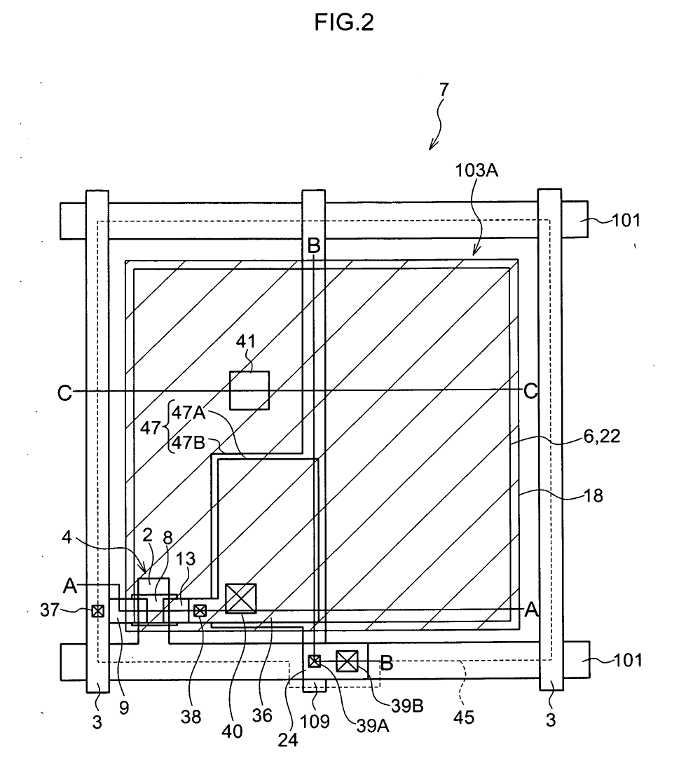

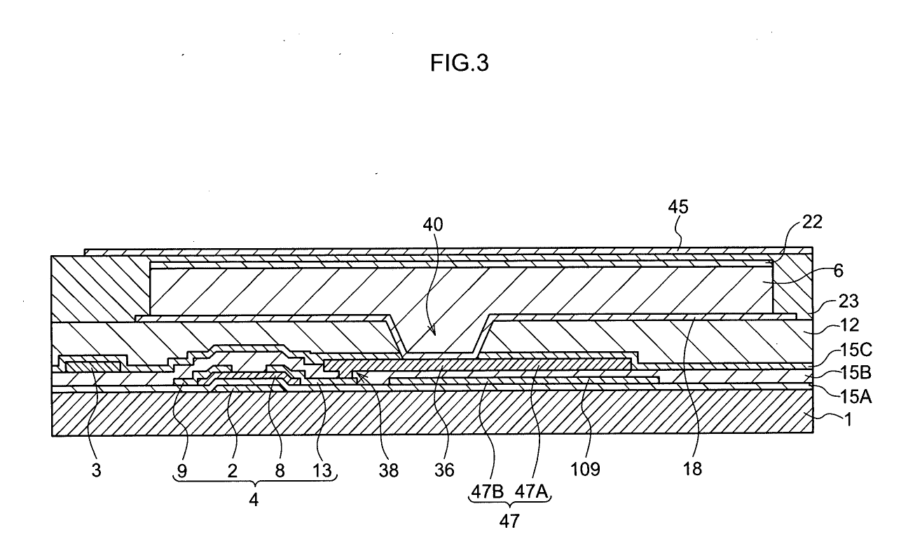

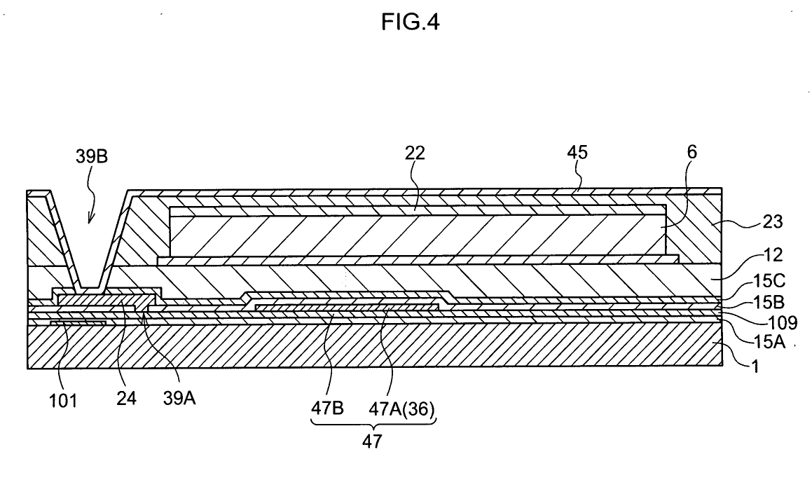

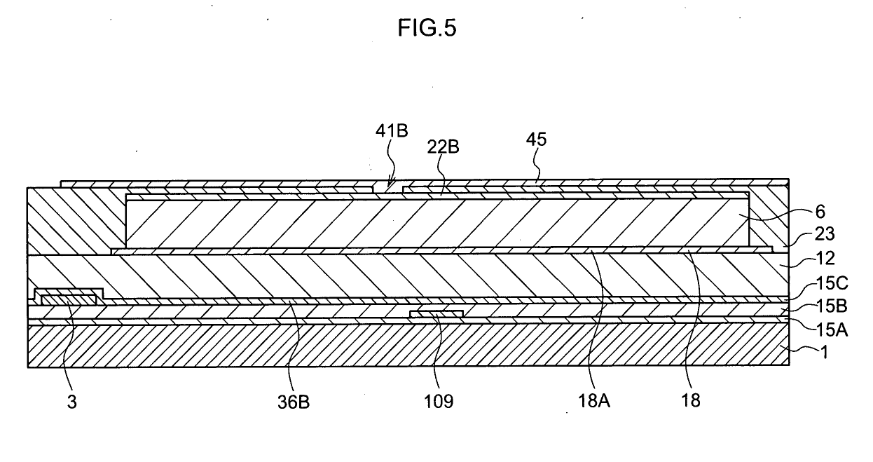

FIG. 2 to FIG. 5 show an example of a configuration of the radiation detector 10 according to the present exemplary embodiment. FIG. 2 illustrates in plan view the structure of a single pixel 7 of the radiation detector 10 according to the present exemplary embodiment. FIG. 3 shows a cross-section taken on line A-A of FIG. 2. FIG. 4 shows a cross-section taken on line B-B of FIG. 2. FIG. 5 shows a cross-section taken on line C-C of FIG. 2.

As shown in FIG. 3 to FIG. 5, the radiation detector 10 of the present exemplary embodiment is formed with an insulating substrate 1 configured from alkali-free glass or the like, on which the scan lines 101, and gate electrodes 2 are formed. The scan lines 101 and the gate electrodes 2 are connected together (see FIG. 2). The wiring layer in which the scan lines 101 and the gate electrodes 2 are formed (this wiring layer is referred to below as the first signal wiring layer) is formed from Al and/or Cu, or a layered film mainly composed of Al and/or Cu. However, the material of the first signal wiring layer is not limited thereto.

A first insulation film 15A is formed above the scan lines 101 and the gate electrodes 2 on one face of the first signal wiring layer, so as to cover the scan lines 101 and the gate electrodes 2. The locations of the first insulation film 15A positioned over the gate electrodes 2 are employed as a gate insulation film in the TFT switches 4. The first insulation film 15A is, for example, formed from SiNₓ or the like by, for example, Chemical Vapor Deposition (CVD) film forming.

An island shape of a semiconductor active layer 8 is formed above the first insulation film 15A on each of the gate electrodes 2. The semiconductor active layer 8 is a channel portion of the TFT switch 4 and is, for example, formed from an amorphous silicon film.

A source electrode 9 and a drain electrode 13 are formed above the aforementioned layer. The wiring layer in which the source electrode 9 and the drain electrode 13 are formed also has the common electrode lines 109 formed therein. The wiring layer in which the signal lines 3, the source electrodes 9 and the common electrode lines 109 are formed (this wiring layer is referred to below as the second signal wiring layer) is formed from Al and/or Cu, or a layered film mainly composed of Al and/or Cu. However, the material of the second signal wiring layer is not limited thereto.

A contact layer (not shown in the drawings) is formed between the semiconductor active layer 8, and both the source electrode 9 and the drain electrode 13. The contact layer is an impurity doped semiconductor layer of, for example, impurity doped amorphous silicon or the like. Each of the TFT switches 4 is configured by the gate electrode 2, the semiconductor active layer 8, the source electrode 9, and the drain electrode 13.

A second insulation film 15B is formed over substantially the whole surface (substantially the entire region) of regions where the pixels 7 are situated above the substrate 1, so as to cover the semiconductor active layers 8, the source electrodes 9, the drain electrodes 13 and the common electrode lines 109. The second insulation film 15B is formed, for example, from SiNₓ or the like, by, for example, CVD film forming.

The signal lines 3, contacts 24, and contacts 36 are formed above the second insulation film 15B. The wiring layer in which the signal lines 3, the contact 24 and the contacts 36 are formed (referred to below as a third signal wiring layer) is formed from Al and/or Cu, or a layered film mainly composed of Al and/or Cu. However, the material of the third signal wiring layer is not limited thereto.

Contact holes 37 (see FIG. 2) are formed in the second insulation film 15B at locations where the signal lines 3 and the source electrodes 9 face each other. Contact holes 38 are formed in the second insulation film 15B at locations where the contacts 36 and the drain electrodes 13 face each other. Contact holes 39A are also formed in the second insulation film 15B at locations where the contacts 24 and the common electrode lines 109 face each other.

The signal lines 3 are connected to the source electrodes 9 through the contact holes 37 (see FIG. 1). The contacts 36 are connected to the drain electrodes 13 through the contact holes 38. The contacts 24 are also connected to the common electrode lines 109 through the contact holes 39A (see FIG. 4).

In the radiation detector 10 according to the present exemplary embodiment, an electrode portion 47A is formed in the area of each of the sensor sections 103 by spreading the contact 36. Further, in the present exemplary embodiment, electrode portions 47B is formed in the area of each of the sensor sections 103 by spreading the common electrode lines 109. The electrode portions 47B are formed to face the electrode portions 47A. Accordingly, in the present exemplary embodiment, the charge storage capacitors 47 are formed by the electrode portions 47A and the electrode portions 47B.

A third insulation film 15C is also formed on one face above the third signal wiring layer, with a coated intermediate insulation film 12 further formed thereon. The third insulation film 15C is formed, for example, from SiNₓ or the like by, for example, CVD film forming. Contact holes 40 are formed through both the intermediate insulation film 12 and the third insulation film 15C at locations facing the contacts 36. Contact holes 39B are also formed through both the intermediate insulation film 12 and the third insulation film 15C at locations facing the contacts 24.

Lower electrodes 18 are formed on the intermediate insulation film 12 so as to fill the respective contact holes 40. The lower electrodes 18 are connected to the contacts 36 at the contact holes 40. The lower electrodes 18 are also connected to the drain electrodes 13 of the TFT switches 4 through the contacts 36. When a semiconductor layer 6, described later, is about 1 μm thick, there is substantially no limitation to the material of the lower electrodes 18 as long as it is a conductive material. The lower electrodes 18 are therefore formed with a conductive metal, such as an aluminum based material, ITO or the like.

However, when the film thickness of the semiconductor layer 6 is thin (about 0.2 to 0.5 μm) there is insufficient light absorption by the semiconductor layer 6. Accordingly, in order to prevent an increase in leak current flow due to light illumination onto each of the TFT switches 4, the lower electrode 18 is preferably an alloy or layered film with a metal having light-blocking ability as a main component.

The semiconductor layer 6 is formed on the lower electrode 18 and functions as a photodiode. In the present exemplary embodiment, a photodiode of PIN structure is employed as the semiconductor layer 6. The semiconductor layer 6 is formed from the bottom with an n⁺ layer, an i layer and a p⁺ layer layered on each other. Note that in the present exemplary embodiment, the lower electrodes 18 are larger than the respective semiconductor layer 6 portions. When the thickness of the semiconductor layer 6 is thin (for example 0.5 μm or less), the TFT switches 4 are preferably covered with a metal having light-blocking ability, in order to prevent light from being incident onto the TFT switches 4.

A separation of 5 μm or greater is preferably secured from the channel of each of the TFT switches 4 to the edge of the light-blocking metal lower electrodes 18, in order to suppress light entry to the TFT switches 4 due to light scattering and reflection within the device.

Individual upper electrodes 22 are formed on each of the semiconductor layers 6. The upper electrodes 22 are, for example, formed using a material having high transmissivity to light, such as ITO, Indium Zinc Oxide (IZO) or the like.

In the radiation detection device 10 according to the present exemplary embodiment, each of the sensor sections 103 is configured by the upper electrodes 22, the semiconductor layers 6, and the lower electrodes 18.

A coated intermediate insulation film 23, with opening 41 corresponding to a portion of the upper electrode 22, is formed on the intermediate insulation film 12 and the upper electrode 22, so as to cover the semiconductor layer 6. Contact holes 39B are formed through the intermediate insulation film 23 at locations corresponding to the contacts 24.

Electrodes 45 are formed on the intermediate insulation film 23 so as to cover the pixel regions. The electrodes 45 are, for example, formed using a material that have high transmissive to light, such as ITO, IZO or the like. The electrodes 45 are connected to the upper electrodes 22 through the openings 41 and are also connected to the contacts 24 through the contact holes 39B. Accordingly, the upper electrodes 22 are electrically connected to the common electrode lines 109 through the contacts 24 and the electrodes 45.

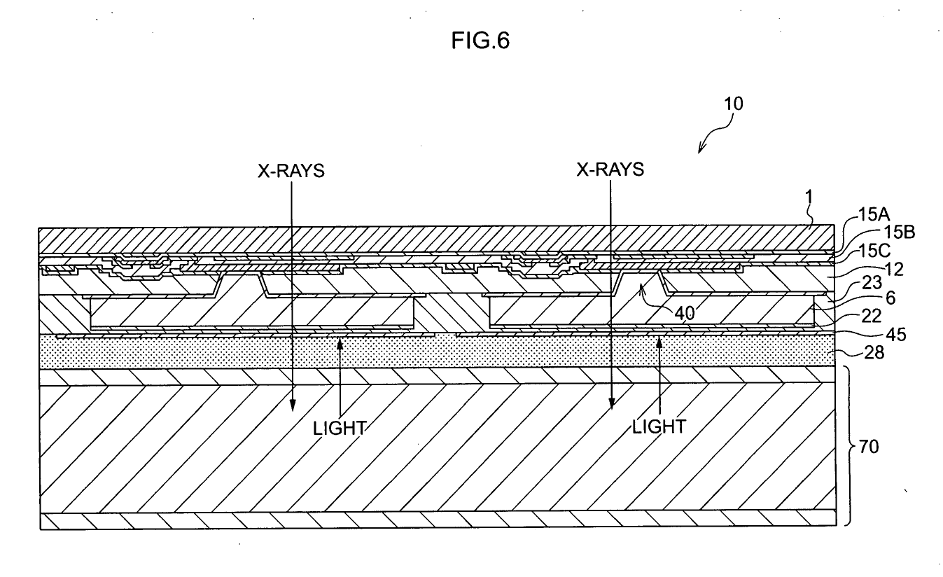

In a radiation detector 10 configured as described, a protection layer 28, as shown in FIG. 6, may be formed from an insulating material with low light absorption characteristics as required. A scintillator 70, configured for example from GOS or the like, may then be attached using an adhesive resin with low light absorption characteristics to the surface of the protection layer 28. The scintillator 70 converts irradiated radiation into light, and emits the light. As shown in FIG. 6, a reflective body made from a material that reflects light is provided at a lower portion of the scintillator 70 in the present exemplary embodiment.

Explanation now follows regarding the principles of operation of the radiographic imaging apparatus 100 constructed as described above.

When X-rays are irradiated from above in FIG. 6, the irradiated X-rays are absorbed by the scintillator 70 and are converted into visible light. Note that the X-rays may also be irradiated from below in FIG. 6. In such cases the irradiated X-rays are absorbed by the scintillator 70 and converted into visible light. The generated light passes through the protection layer 28 of adhesive resin, and is illuminated onto the respective sensor sections 103.

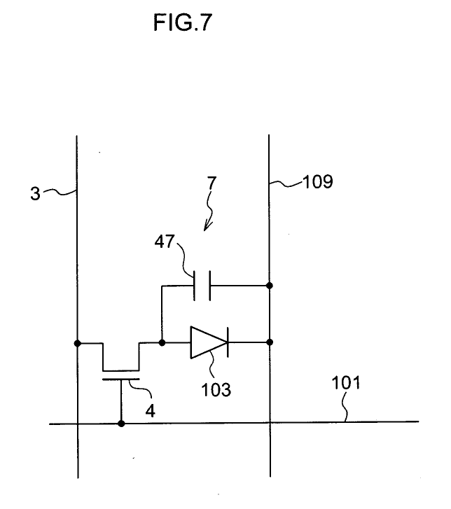

FIG. 7 illustrates an equivalent circuit diagram focusing on a single of the pixels 7 of the radiation detector 10 according to the present exemplary embodiment.

Charges are generated in the sensor section 103 on irradiation with radiation.

The charge storage capacitors 47 are electrically connected in parallel to the sensor sections 103 in the radiation detector 10 according to the present exemplary embodiment. The charge generated in each of the sensor sections 103 accordingly accumulates in both the sensor section 103 and the charge storage capacitor 47 until the potential of the upper electrode 22A reaches the same potential as the bias voltage Vd.

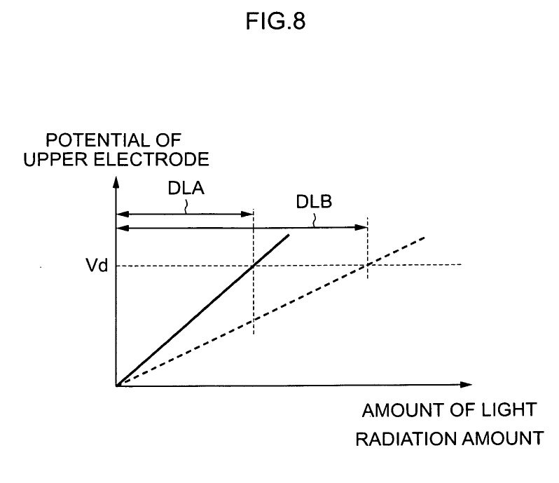

In the radiation detector 10 of the present exemplary embodiment, manner in which the potential of the upper electrode 22 rises due to the accumulation of charge, differs according to the capacity of each of the charge storage capacitors 47. As shown by the solid line in FIG. 8, high gain characteristics are exhibited when the capacity of the charge storage capacitor 47 is small, with the potential of the upper electrode 22 rising fast. A dynamic range of the sensor section 103 is range DLA until the potential of the upper electrode 22A reaches the same potential as the bias voltage Vd. However, the greater the capacity of the charge storage capacitor 47, the lower the gain characteristics, as shown by the intermittent line in FIG. 8, and the dynamic range of the sensor section 103 exhibits as a range DLB.

For example, in a case in which the capacity of the photo diode of 1 pF with no charge storage capacitor provided, the saturated charge amount (namely, when the photo diode lower electrode reaches the bias voltage) will be achieved with a radiation amount of 3 mR. In contrast, by employing the configuration of the present invention with an accumulation capacitor of 0.5 pF disposed electrically connected in parallel to the photo diode, the saturated charge amount becomes 1.5 times the previous case, and as a result the dynamic range can be extended to 4.5 mR.

Accordingly, the radiation detector 10 of the present exemplary embodiment can change the gain characteristics by changing the saturated charge amount, through changing the capacity of the charge storage capacitors 47. The capacity of the charge storage capacitor 47 can be determined and the charge storage capacitors 47 in the present exemplary embodiment configured to give gain characteristics such that the dynamic range of the output electrical signal (the saturated charge amount) matches the detection range of the amplifier. Accordingly, the radiation detector 10 of the present exemplary embodiment may match the detection range of the internal amplification circuit in each of the signal detection circuits 105 and the output characteristics of the output electrical signal set. Thus, the present exemplary embodiment may eliminate the mismatch between the dynamic range of the electrical signal output from the radiation detector 10 and the detection range of the amplifier.

In the radiation detector 10 according to the present exemplary embodiment, the common electrode lines 109 are provided in the sensor section 103 below where light is generated in the scintillator 70. The common electrode lines 109 are provided overlapping with the sensor sections 103, with the third insulation film 15C and the intermediate insulation film 12 interposed between the common electrode lines 109 and the sensor sections 103. The common electrode lines 109 are connected to the sensor sections 103 through the contacts 24. The radiation detector 10 of the present exemplary embodiment can accordingly prevent the common electrode lines 109 from blocking light onto the reception surface area of the sensor section 103. Consequently, the present exemplary embodiment may increase the light reception surface area of the radiation detector 10. This is particularly effective for securing light reception surface area when sensor sections are miniaturized with a high degree of miniaturization.

In the radiation detector 10 of the present exemplary embodiment one electrode 47B of each of the charge storage capacitors 47 is formed in the second signal wiring layer in which the source electrodes 9 and the drain electrodes 13 of the TFT switches 4 are formed. Accordingly, the radiation detector 10 of the present exemplary embodiment may suppress an increase in the number of wiring layers for forming the charge storage capacitors 47. The present exemplary embodiment can thereby simplify fabrication processes for the radiation detector 10.

Note that the configuration of the radiographic imaging apparatus 100 and the configuration of the radiation detector 10 explained in the above exemplary embodiment are merely examples thereof, and obviously various modifications are possible within a scope not departing from the spirit of the present invention.

In the above exemplary embodiment, a case in which each of the common electrode lines 109 is provided in parallel to each of the respective signal lines 3, has been described. However, the present invention is not limited thereto. For example, each of the common electrode lines 109 may be provided in parallel to each of the respective scan lines 101.

In the above exemplary embodiment, a case in which the common electrode lines 109 and the electrodes 47B are formed in the second signal wiring layer, and the contacts 36 are formed in the third signal wiring layer, has been described. However, the present invention is not limited thereto. For example, the common electrode lines 109 and the electrodes 47B may be formed in the first signal wiring layer. In such cases, the contact holes 40 may also be formed in the second insulation film 15B, and the contacts 36 formed in the second signal wiring layer.

The common electrode lines 109 and the charge storage capacitors 47 may also be formed in the same layer as the sensor sections 103, or may be formed in the sensor sections 103 above where light is generated in the scintillator 70.

In the present exemplary embodiment, a case in which the present exemplary embodiment is applied to the radiographic imaging apparatus 100 that detects an image by detecting X-rays, has been described. However, the present invention is not limited thereto. For example, radiation employed may be X-rays and also visible light, ultraviolet light, infrared light, gamma rays, or a particle beam.

What is claimed is:

1. A radiation detector comprising:
a plurality of scan lines provided parallel to each other;
a plurality of signal lines provided parallel to each other and intersecting with the scan lines;
a plurality of sensor sections, provided at intersecting portions of the scan lines and the signal lines, that generate charges due to irradiation of radiation, and that accumulate charges according to an amount of irradiated radiation;
a plurality of bias lines that apply a bias voltage to the plurality of sensor sections; and
a plurality of charge storage capacitors, provided for each of the plurality of sensor sections, that accumulate charges generated in the sensor sections and are electrically connected to the bias lines in parallel to the sensor sections.

2. The radiation detector of claim 1, further comprising a light emitting section, provided above a detection region where the plurality of sensor sections are provided, that generates light according to irradiated radiation,
wherein the plurality of bias lines are provided at a downstream side from the sensor portions in a direction of the light generated in the light emitting sections, such that the bias lines overlap with the sensor sections with an insulation film disposed between the sensor sections and the bias lines, the bias lines being connected to the sensor sections through contacts formed through the insulation film.

3. The radiation detector of claim 1, further comprising a thin film transistor that reads charge generated in the plurality of sensor sections,
wherein the plurality of charge storage capacitors are configured with two electrodes and an insulation film disposed between the two electrodes, and one of the electrodes is formed in a wiring layer in which the thin film transistor is formed.

4. The radiation detector of claim 2, further comprising a thin film transistor that reads charge generated in the plurality of sensor sections,
wherein the plurality of charge storage capacitors are configured with two electrodes and an insulation film disposed between the two electrodes, and one of the electrodes is formed in a wiring layer in which the thin film transistor is formed.

5. The radiation detector of claim 3, wherein the insulation film of the plurality of charge storage capacitors is formed by an insulation layer that configures a gate insulation film of the thin film transistor.

6. The radiation detector of claim 4, wherein the insulation film of the plurality of charge storage capacitors is formed by an insulation layer that configures a gate insulation film of the thin film transistor.
